(19) United States
(12) Patent Application Publication
(10) Pub. No.: US 2024/0063740 A1
(43) Pub. Date: Feb. 22, 2024

(54) METHODS OF REAL-TIME PREDICTION OF TORQUE MODULATION PARAMETERS

(71) Applicant: Tula eTechnology, Inc., San Jose, CA (US)

(72) Inventors: Paul Carvell, San Jose, CA (US); Siyu Leng, San Jose, CA (US); Zakirul Islam, San Jose, CA (US)

(73) Assignee: Tula eTechnology, Inc., San Jose, CA (US)

(21) Appl. No.: 18/219,193

(22) Filed: Jul. 7, 2023

Related U.S. Application Data
(60) Provisional application No. 63/399,629, filed on Aug. 19, 2022.

(51) Int. Cl. H02P 23/00; G06F 30/20

(52) U.S. Cl. CPC H02P 23/0022; G06F 30/20

(57) ABSTRACT

A method of predicting torque modulation parameters of an electric machine based on operating conditions of the electric machine includes generating a data set for torque modulation parameters of an electric machine for the different operating conditions of the electric machine. The method also includes relating the torque modulation parameters to the operating conditions of the electric machine with a model and loading the model into a controller of the electric machine. The method also includes predicting the torque modulation parameters of the electric machine for the operating conditions of the electric machine using the model in real-time. The method may include adjusting the torque modulation parameters of the electric machine based on the predicted torque modulation parameters.

### CROSS-REFERENCE TO RELATED APPLICATION

This application claims benefit of, and priority to, U.S. patent application Ser. No. 63/399,629, filed Aug. 19, 2022, the entire contents of which are hereby incorporated by reference.

### BACKGROUND

### 1. Technical Field

The present disclosure relates to pulsed control of electric machines and, more specifically, to methods of real-time prediction of torque modulation parameters. The methods may predict the torque modulation parameters in view of DC input voltage, State of Charge (SOC) of a battery, speed, or temperature.

### 2. Discussion of Related Art

Electric motors are known to be efficient at providing continuous torque to driven equipment. It has been found that methods of pulsing an electric motor, such as Dynamic Motor Drive (DMD), with an optimal efficient torque at a reduced duty cycle to deliver a target torque below the optimal efficient torque can improve the efficiency of the electric motor.

The optimal efficient or pulse torque, maximum pulse or DMD torque (above which pulse or DMD gain is negative), and torque-ramp up/down rate can affect the efficiency improvement from implementing DMD or pulsed control of an electric motor. Deviation in these parameters may result in lower efficiency, loss of current control, or both which defeats the purpose of DMD.

For battery powered electric vehicles, battery voltage varies significantly depending on the DC input voltage or State of Charge (SOC) of the battery, e.g., between full charge and full discharge. As a result, the optimal efficient torque, maximum DMD torque, and the torque-ramp up/down rate are constantly changing as the SOC of the battery changes. In addition, the optimal efficient torque, maximum DMD torque, and the torque-ramp up/down rate may change as the speed of the motor changes and/or as the temperature of the motor or the inverter changes.

### SUMMARY

This disclosure relates generally to methods of real time adjustment of torque modulation or DMD parameters in view of operating conditions of the system. The real time adjustment of torque modulation parameters may maintain higher DMD gain and/or acceptable noise, vibration, and harshness (NVH) under different operating conditions. The DMD parameters may include the instantaneous optimal efficient torque or pulse torque, the maximum DMD torque, and/or the torque-ramp up/down rate. The operating conditions of the system may include, but not be limited to, DC input voltage, SOC of the battery, speed of the electric motor, temperature of the electric motor, and/or the temperature of the inverter.

In aspects of the present disclosure, a method of predicting torque modulation parameters of an electric machine based on operating conditions of the electric machine includes generating a data set for torque modulation parameters of an electric machine for the different operating conditions of the electric machine. The method also includes relating the torque modulation parameters to the operating conditions of the electric machine with a model and loading the model into a controller of the electric machine. The method also includes predicting the torque modulation parameters of the electric machine for the operating conditions of the electric machine using the model in real-time. The method may include adjusting the torque modulation parameters of the electric machine based on the predicted torque modulation parameters.

In aspects, relating the torque modulation parameters to the operating conditions of the electric machine with the model includes developing a mathematical equation for the relationship between the torque modulation parameters and the operating conditions using the data sets. Loading the model into the controller may include generating a baseline data set for the torque modulation parameters for different operating conditions. Predicting the torque modulation parameters for the operating conditions may include utilizing the baseline data set and the mathematical equation to predict the torque modulation parameters.

In some aspects, relating the torque modulation parameters to the operating conditions of the electric machine with the model includes training a machine learning model for the relationship between the torque modulation parameters and the operating conditions using the data sets. Loading the model into the controller may include loading the machine learning model into the controller. Predicting the torque modulation parameters for the operating conditions may include utilizing the machine learning model in the controller to predict the torque modulation parameters.

In certain aspects, generating the data set for the torque modulation parameters of an electric machine for different operating conditions of the electric machine includes the torque modulation parameters including maximum efficient pulse torque, maximum DMD torque for pulse control, or maximum torque ramp up/down. Generating a data set for torque modulation parameters of an electric machine for different operating conditions of the electric machine includes the operating conditions including DC input voltage, state of charge of a battery, speed of the electric machine, temperature of the electric machine, or temperature of an inverter of the electric machine.

In another aspect of the present disclosure, a controller for controlling an electric machine includes a memory and a processing device that is operatively coupled to the memory. The processing device stores a model relating operating conditions of the electric machine to torque modulation parameters of the electric machine and predicts the torque modulation parameters of the electric machine for the operating conditions of the electric machine using the model in real-time.

In aspects, the processing device further adjusts the torque modulation parameters of the electric machine based on the predicted torque modulation parameters. Storing the model relating operating conditions to the electric machine includes storing a mathematical equation for the relationship between the torque modulation parameters and the operating conditions. Storing the model relating the operating conditions to the electric machine may include storing a machine learning model for the relationship between the torque modulation parameters and the operating conditions. Predicting the torque modulation parameters for the operating conditions includes utilizing the machine learning model to predict the torque modulation parameters.

In another aspect of the present disclosure, a non-transitory computer-readable medium storing instructions that, when executed by a processing device, cause the processing device to control an electric machine by storing a model relating operating conditions of the electric machine to torque modulation parameters of the electric machine and predicting the torque modulation parameters of the electric machine for the operating conditions of the electric machine using the model in real-time.

In aspects, the processing device further causes the processing device to adjust the torque modulation parameters of the electric machine based on the predicted torque modulation parameters. Storing the model relating operating conditions to the electric machine includes storing a mathematical equation for the relationship between the torque modulation parameters and the operating conditions. Storing the model relating the operating conditions to the electric machine may include storing a machine learning model for the relationship between the torque modulation parameters and the operating conditions. Predicting the torque modulation parameters for the operating conditions includes utilizing the machine learning model to predict the torque modulation parameters.

Further, to the extent consistent, any of the embodiments or aspects described herein may be used in conjunction with any or all of the other embodiments or aspects described herein.

### BRIEF DESCRIPTION OF THE DRAWINGS

Various aspects of the present disclosure are described hereinbelow with reference to the drawings, which are incorporated in and constitute a part of this specification, wherein:

FIG. 1 is a representative Torque/Speed/Efficiency graph illustrating the energy conversion efficiency of a representative electric motor under different operating conditions;

FIG. 2 is a graph illustrating a pulsed torque signal applied to an electric motor;

FIG. 3 illustrates a pulsed controlled electric machine in accordance with a non-exclusive embodiment;

FIG. 4 illustrates a variation of maximum efficient torque for an example electric machine for different input voltages and speeds;

FIG. 5 illustrates a variation of maximum torque ramp up rate for an example electric machine under different input voltages and speeds;

FIG. 6 illustrates a variation of maximum efficient torque for an example electric machine under different winding temperatures of the electric machine;

FIGS. 7A-7D illustrate a procedure for developing and using a mathematical equation for predicting DMD parameters in real-time for a variety of operating conditions in accordance with an embodiment of the present disclosure;

FIG. 8 illustrate a comparison of actual maximum efficient torque versus predicted maximum efficient torque using DC input voltage as a variable with the mathematical equation method of the present disclosure;

FIG. 9A illustrates a comparison of actual torque ramp up rate and predicted torque ramp up rate using DC input voltage as a variable with the mathematical equation method of the present disclosure;

FIG. 9B illustrates a comparison of actual torque ramp down rate and predicted torque ramp down rate using DC input voltage as a variable with the mathematical equation method of the present disclosure;

FIG. 10 illustrates a comparison of actual maximum efficient torque versus predicted maximum efficient torque using a DC Input Voltage of the electric machine or a State of Charge of the Battery System as a variable with the mathematical equation method of the present disclosure;

FIGS. 11A-11D illustrate a procedure for training and using machine learning models for identifying torque modulation parameters in real-time in accordance with an embodiment of the present disclosure;

FIG. 12 illustrates a comparison of a maximum efficiency torque versus RPM of an example electrically excited synchronous machine for various DC voltages of the electrically excited synchronous machine;

FIG. 13 illustrates a maximum efficiency torque with respect to RPM of an example electrically excited synchronous machine for various winding temperatures of the electrically excited synchronous machine; and

FIG. 14 is a block diagram of an example controller that may perform one or more of the operations described herein.

### DETAILED DESCRIPTION

The present disclosure will now be described more fully hereinafter with reference to example embodiments thereof with reference to the drawings in which like reference numerals designate identical or corresponding elements in each of the several views. These example embodiments are described so that this disclosure will be thorough and complete, and will fully convey the scope of the disclosure to those skilled in the art. Features from one embodiment or aspect can be combined with features from any other embodiment or aspect in any appropriate combination. For example, any individual or collective features of method aspects or embodiments can be applied to apparatus, product, or component aspects or embodiments and vice versa. The disclosure may be embodied in many different forms and should not be construed as limited to the embodiments set forth herein; rather, these embodiments are provided so that this disclosure will satisfy applicable legal requirements. As used in the specification and the appended claims, the singular forms “a,” “an,” “the,” and the like include plural referents unless the context clearly dictates otherwise. In addition, while reference may be made herein to quantitative measures, values, geometric relationships or the like, unless otherwise stated, any one or more if not all of these may be absolute or approximate to account for acceptable variations that may occur, such as those due to manufacturing or engineering tolerances or the like.

As used herein, the term “machine” is intended to be broadly construed to mean both electric motors and generators. Electric motors and generators are structurally very similar with both including a stator having a number of poles and a rotor. When a machine is operating as a motor, it converts electrical energy into mechanical energy and when operating as a generator, the machine converts mechanical energy into electrical energy. The electric machines detailed herein may be an electrically excited synchronous machine (EESM). An EESM may also be referend to as a wound rotor synchronous machine (WRSM) or a wound field synchronous machine (WFSM).

Modern electric machines have relatively high energy conversion efficiencies. The energy conversion efficiency of most electric machines, however, can vary considerably based on their operational load. With many applications, a machine is required to operate under a wide variety of different operating load conditions. As a result, machines typically operate at or near the highest levels of efficiency at certain times, while at other times, they operate at lower efficiency levels.

Battery powered electric vehicles provide a good example of an electric machine operating at a wide range of efficiency levels. During a typical drive cycle, an electrical vehicle will accelerate, cruise, de-accelerate, brake, corner, etc. Within certain rotor speeds and/or torque ranges, the electric machine operates at or near is most efficient operating point, i.e., its “sweet spot.” Outside of these ranges, the operation of electric machine is less efficient. As driving conditions change, the machine transitions between high and low operating efficiency levels as the rotor speed and/or torque changes. If the electric machine could be made to operate a greater proportion of a drive cycle in high efficiency operating regions, the range of the vehicle for a given battery charge level would be increased. Since the limited range of battery powered electric vehicles is a major commercial impediment to their use, extending the operating range of the vehicle is highly advantageous. A need therefore exists to operate electric machines, such as motors and generators, at higher levels of efficiency.

The present application relates generally to pulsed control electric machines that can be operated in a continuous or pulsed manner. By pulsed control, the machine is intelligently and intermittently pulsed on and off to both (1) meet operational demands while (2) improving overall efficiency compared to continuous control. More specifically, under selected operating conditions, an electric machine is intermittently pulse-driven at more efficient energy conversion operating levels to deliver the desired average output torque more efficiently than would be attained by continuous control. Pulsed control results in deliberate modulation of the electric machine torque; however, the modulation is managed in such a manner that levels of noise or vibration are minimized for the intended application.

For the sake of brevity, the pulsed control of electric machines as provided herein is described in the context of an electric vehicle. This explanation, however, should not be construed as limiting in any regard. On the contrary, the pulse control as described herein can be used for many types of electric machines including both electric motors and generators. In addition, pulsed control of such electric machines may be used in any application, not just limited to electric vehicles. In particular, pulsed control may be used in systems that require lower acceleration and deceleration rates than vehicle applications, such as electric motors for heating, cooling, and ventilating systems.

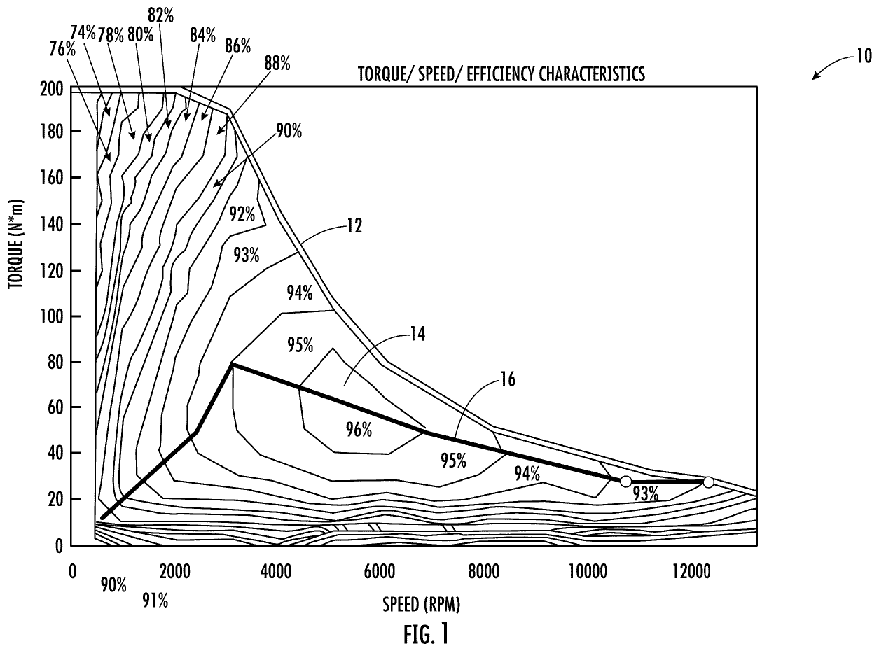

Referring to FIG. 1, an example vehicle motor efficiency map 10 under operating conditions is illustrated. The map 10 plots torque (N*m) along the vertical axis as a function of motor speed (RPM) along the horizontal axis. The maximum steady-state output torque is given by curve 12. The example vehicle motor efficiency map is shown to help illustrate an increase in efficiency of an electric machine that may be provided by pulsed control of the electric machine.

The area under the peak-torque/speed curve 12 is mapped into a plurality of regions, each labeled by an operational efficiency percentage. For the particular motor shown, the following characteristics are evident:
The most efficient or “sweet-spot” region of its operating range is the operating region labeled 14, which is generally in the range of 4,500-6,000 RPM with a torque output in the range of about 40-70 N*m. In region 14, the energy conversion efficiency is on the order of 96%, making it the “sweet spot”, where the motor is operating in its most efficient operating range.
As the motor speed increases beyond approximately 6,000+RPM, the efficiency tends to decrease, regardless of the output torque.
As the output torque increases beyond 70 N*m or falls below 40 N*m, the efficiency percentage tends to decrease from its peak, in some situations rather significantly. For example, when the motor is operating at approximately 2,000 RPM and an output torque of 100 N*m, the efficiency is approximately 86%. When torque output falls below about 30 N*m, regardless of the motor speed, the efficiency drops, approaching zero at zero load.
At any particular motor speed, there will be a corresponding most efficient output torque, which is diagrammatically illustrated by a maximum efficiency curve 16.

The map 10 as illustrated was derived from an electric motor used in a 2010 Toyota Prius. It should be understood that this map 10 is merely illustrative and should not be construed as limiting in any regard. A similar map can be generated for just about any electric motor, for example a 3-phase induction motor, regardless of whether used in a vehicle or in some other application.

As can be seen from the map 10, the motor is generally most efficient when operating within the speed and torque ranges of the sweet spot 14. If the operating conditions can be controlled so that the motor operates a greater proportion of time at or near its sweet spot 14, the overall energy conversion efficiency of the motor can be significantly improved.

From a practical point of view, however, many driving situations dictate that the motor operate outside of the speed and torque ranges of the sweet spot 14. In electric vehicles it is common to have no transmission and as such have a fixed ratio of the electric motor rotation rate to the wheel rotation rate. In this case, the motor speed may vary between zero, when the vehicle is stopped, to a relatively high RPM when cruising at highway speeds. The torque requirements may also vary widely based on factors such as whether the vehicle is accelerating or decelerating, going uphill, going downhill, traveling on a level surface, braking, etc.

As can be seen in FIG. 1, at any particular motor speed, there will be a corresponding most efficient or optimal efficient torque which is diagrammatically illustrated by maximum efficiency curve 16. From a conceptual standpoint, when the desired motor torque is below the maximum efficiency curve 16 for the current motor speed, the overall efficiency of the motor can be improved by pulsing the motor at an optimal efficient torque, so as to operate the motor a proportion of time at or near its maximum efficiency curve and the remainder of the time at a low or zero torque output level. The average torque generated is controlled by controlling the duty cycle of sweet spot operation.

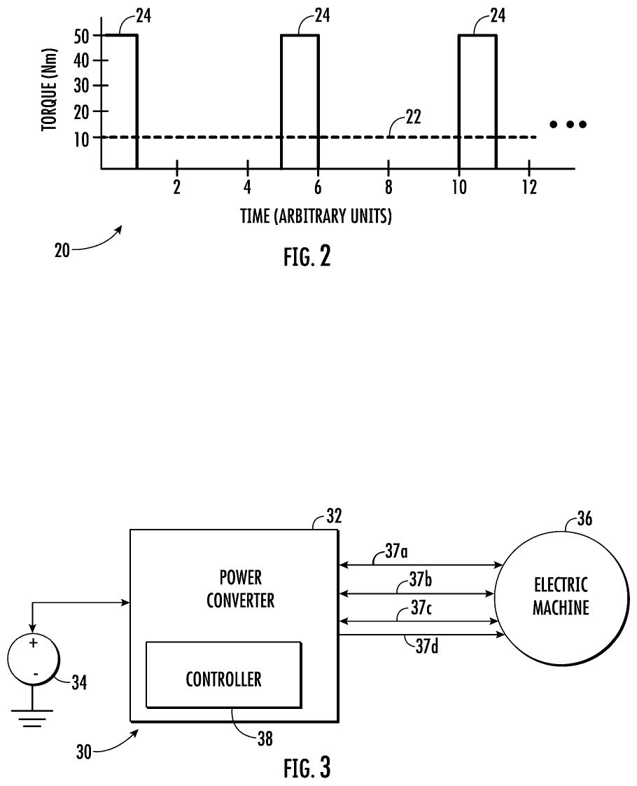

Referring to FIG. 2, a graph 20 plotting torque on the vertical axis versus time on the horizontal axis is illustrated. During conventional operation, the motor would continuously generate 10 N*m, indicated by dashed line 22, so long as the desired torque remained at this value. With pulsed-control operation, the motor is pulsed with a current pulse signal, as represented by pulses 24, to deliver 50 N*m of torque for 20% of the time. The remaining 80% of the time, the motor is off. The net output of the motor therefore meets the operational demand of an average torque level of 10 N*m. Since the motor operates more efficiently when it is delivering 50 N*m than when it delivers a continuous torque of 10 N*m, the motor's overall efficiency can thus be improved by pulsing the motor using a 20% duty cycle while still meeting the average torque demand. Thus, the pulsed operation provides a higher energy efficiency than the continuous operation.

In the above example, the duty cycle is not necessarily limited to 20%. As long as the desired motor output, does not exceed 50 N*m, the desired motor output can be met by changing the duty cycle. For instance, if the desired motor output changes to 20 N*m, the duty cycle of the motor operating at 50 N*m can be increased to 40%; if the desired motor output changes to 40 N*m, the duty cycle can be increase to 80%; if the desired motor output changes to 5 N*m, the duty cycle can be reduced to 10% and so on. Generally, pulsed motor control can potentially be used advantageously any time that the desired motor torque falls below the maximum efficiency curve 16 of FIG. 1.

On the other hand, when the desired motor torque is at or above the maximum efficiency curve 16, the motor may be operated in a conventional (continuous or non-pulsed) manner to deliver the desired torque. Pulsed operation offers opportunity for efficiency gains when the motor is required to deliver an average torque below the torque corresponding to its maximum operating efficiency point.

It should be noted that torque values and time scale provided in FIG. 2 are merely illustrative and are not intended to be limiting in any manner. In actual motor pulsing embodiments, the pulse duration used may widely vary based on the design needs of any particular system. In general, however, the scale of the periods for each on/off cycle is expected to be on the order of 10 milliseconds (ms) to 0.10 seconds (i.e., pulsing at a frequency in the range of 10 to 100 Hz). Furthermore, there are a wide variety of different electric machines, and each electric machine has its own unique efficiency characteristics. Further, at different motor speeds, a given motor will have a different efficiency curve. The nature of the curve may vary depending on the particular electric machine or a particular application. For example, torque output need not be flat topped as depicted in FIG. 2 and/or the torque need not go to zero during the off periods but may be some non-zero value. Regardless of the particular curve used, however, at some proportion of the time the electric machine is operating is preferably at or near its highest efficiency region for a given electric machine.

Power inverters are known devices that are used with electric motors for converting a DC power supply, such as that produced by a battery or capacitor, into multi-phase AC input power, e.g., three-phase AC input power, applied to motor stator windings. In response, the stator windings generate the RMF as described above.

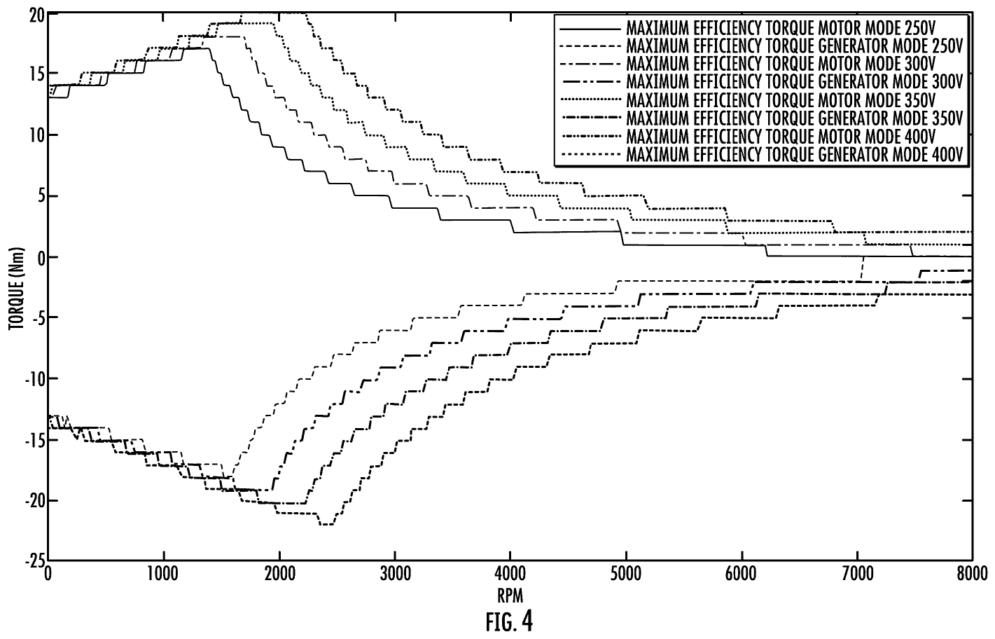

Referring to FIG. 3, a diagram of an example power controller 30 for pulsed operation of an electric machine is illustrated. The power controller 30 includes a power converter 32, a DC power supply 34, and an electric machine 36. In this non-exclusive embodiment, the power converter 32 comprises a controller 38. The controller 38 may be used to control the electric machine 36 in a continuous control mode or pulsed/DMD control mode. The power converter 32 may be operated as a power inverter or power rectifier depending on the direction of energy flow through the system. When the electric machine is operated as a motor, the power converter 32 is responsible for generating three-phased AC power from the DC power supply 34 to drive the electric machine 36. The three-phased input power, denoted as phase A 37a, phase B 37b, and phase C 37c, is applied to the windings of the stator of the electric machine 36 for generating the RMF as described above. The lines depicting the various phases, 37a, 37b, and 37c are depicted with arrows on both ends indicating that energy can flow both from the power converter 32 to the electric machine 36 when the machine is used as a motor and that energy can flow from the electric machine 36 to the power converter 32 when the machine is used as a generator. When the electric machine 36 is operating as a generator, the power converter 32 operates as a power rectifier and the AC power coming from the electric machine 36 is converted to DC power being stored in the DC power supply 34. The line depicting the field current, 37d carries a DC field current that typically is unidirectional for both the motor and generator operating modes.

The controller 38 is responsible for selectively pulsing the three-phased input power. During conventional (i.e., continuous) operation, the three-phased and field coil input power is continuous or not pulsed. On the other hand, during pulsed operation, the three-phased and field coil input power is pulsed. Pulsed operation may be implemented, in non-exclusive embodiments, using any of the approaches described herein, such as but not limited to the approaches described below.

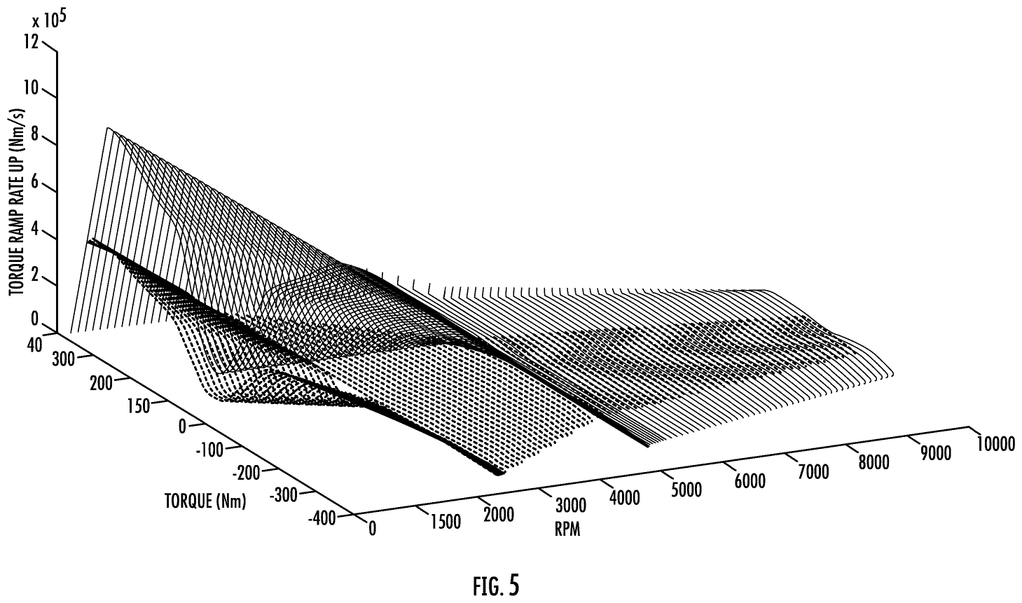

With reference to FIGS. 4-6, the variation of the torque modulation parameters with respect to different operating conditions are shown for two example electric machines. Initially referring to FIG. 4, the variation of maximum efficient torque line for different input voltages or state of charge (SOC) for a battery and speeds of a synchronous reluctance machine (SynRM) are shown. As shown, as the SOC of the battery decreases, the maximum efficient torque is also reduced in a motor mode and is increased in the generator mode. With respect to speed, as the speed initially increases the maximum efficient torque to a point and then decreases once a maximum is reached between 1500 and 2500 RPM depending on the SOC for the motor mode and decreases until the minimum is reached before increasing in the generator mode.

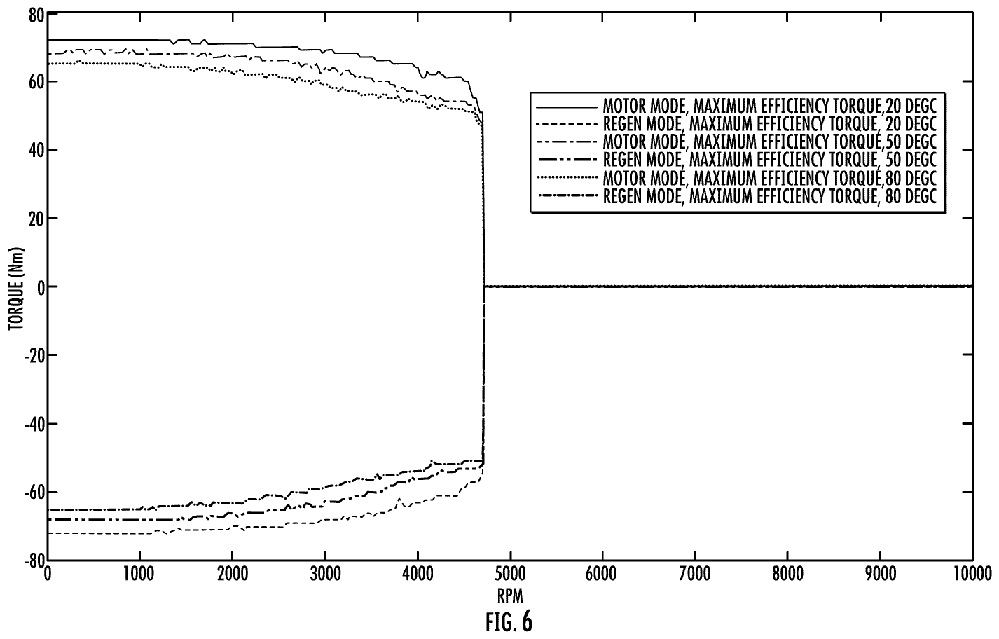

FIG. 5 illustrates the variation of the maximum torque ramp up rate for an interior permanent magnet (IPM) machine under different DC input voltages and speeds. As shown, the maximum torque ramp up rate drops quickly as the speed increases and then levels off. The trend of the torque vs. speed is similar for both DC input voltages, or SOC, but with a higher starting point when the DC input voltage is higher. In addition, as the torque increases, the maximum torque ramp up rate also increases.

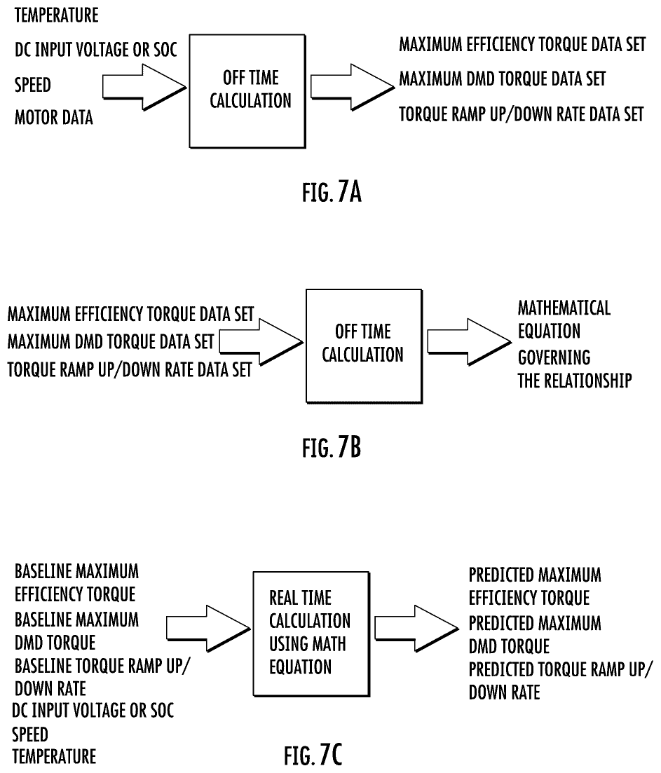

With particular reference to FIG. 6, the variation of the maximum efficient torque is shown for an IPM machine for different winding temperatures and speeds. As shown, the maximum efficient torque of the electric machine decreases as the winding temperature increases for the electric machine. With respect to speed, for an IPM machine, above a certain speed, safe control of the back EMF may use field weakening, which in turn constrains the opportunity to eliminate inverter activity. The inverter operation may reduce the region where DMD can improve system efficiency. In other words, field weakening control of IPM machines may necessitate the stator inverter operation above a certain speed, limiting the opportunity of DMD gain in IPM machines. This is shown in FIG. 6, where above 4750 rpm, maximum efficient torque drops to zero, meaning no opportunity for DMD gain.

For pulsed or DMD operation, the maximum DMD torque is the boundary torque value to go to in pulsed control or DMD control and above which the inverter should switch to continuous control to minimize energy loss and maximize efficiency. In addition, the maximum torque ramp up/down rate that is implemented by the inverter so that DC Input Voltage (or SOC of battery) can be fully utilized is important for maintaining current control.

For DMD operation of the electric machine it is important to predict the torque modulation or DMD parameters in view of the current operating conditions of the electric machine. As shown in FIGS. 4-6, as the operating conditions of the electric machine change, the DMD parameters also change. As such, using a fixed maximum efficient torque, a fixed maximum DMD torque, and/or a fixed torque ramp up/down rate would result in excessive energy loss. With respect to using a fixed torque ramp up/down rate may result in a relatively conservative torque pulse trajectory. For this reason, it is important to predict the DMD parameters in real-time to maximize the efficiency of DMD operation of the electric machine. However, real-time computation of the DMD parameters is not practical due to the computational power required for the computation, e.g., the controller 38 (FIG. 3) may not have the computational power to predict the DMD parameters in real-time. In addition, while off time or offline computation of look up tables can be completed, searching through the look up tables may not be practical in real-time due to the amount of storage required to store the look up table and the complicacy of the data table.

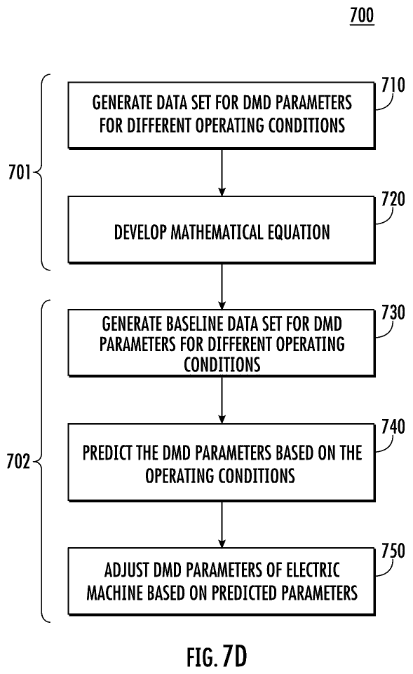

FIGS. 7A-7D illustrate a procedure for developing and using a mathematical equation to predict DMD parameters in real-time for a variety of operating conditions in accordance with an embodiment of the present disclosure. In particular, FIG. 7D illustrates a method 700 for developing and using a mathematical equation for predicting DMD parameters in real-time. The method 700 includes a method 701 of defining relationships between DMD parameters and operating conditions and method 702 of predicting DMD parameters in real-time based on operating conditions of the electric machine. The method 701 includes generating a data set for the actual DMD parameters for a variety of operating conditions of the electric motor (Step 710). The DMD parameters may include the optimal efficient torque or optimal pulse torque, the maximum DMD torque line, and/or the maximum torque ramp up/down rate for the electric motor for the operating conditions. The operating conditions may include DC input voltage or SOC of the battery, speed of the electric machine, and/or the temperature of the electric machine or the inverter.

From the data set, one or more mathematical equations are developed to define the relationship between the DMD parameters and the operating conditions (Step 720). The mathematical equations may be developed using a variety of methods including, but not limited to, curve fitting, regression analysis, and numerical methods. The mathematical equations may be developed with the assistance of one or more software programs including, but not limited to, C programming and MATLAB®.

Once the relationship between the DMD parameters and the operating conditions are defined via method 701, the method 702 is implemented to predict the DMD parameters in real-time with the mathematical equation developed by the method 701. To predict the DMD parameters, a baseline lookup table may be stored in the memory of a controller, e.g., controller 38 (FIG. 3) (Step 730). The baseline lookup table may include a DMD parameter based on one or more operating conditions. For example, the baseline lookup table may include the optimal efficient torque or pulse torque, the maximum DMD torque, or the maximum torque ramp up/down rate in view of the operating conditions. With the baseline lookup table stored, the mathematical equations developed from the method 701 are used to predict the DMD parameters based on the operating conditions (Step 740). Using a baseline lookup table may include using a look up table to predict a single DMD parameter and using one or more mathematical equation to predict the remaining DMD parameters.

The controller may adjust the DMD parameters of the electric machine in view of the predicted parameters (Step 750). Adjusting the DMD parameters of the electric machine may increase an efficiency of the electric machine. In some embodiments, adjusting the DMD parameters may result in the electric machine transitioning to continuous control mode instead of pulsed control mode.

Using a baseline lookup table with the mathematical equations to predict the DMD parameters based on the operating conditions may allow for real-time prediction of the DMD parameters. The mathematical equations or the baseline lookup table may alleviate resources usage, e.g., storage and processing power, to predict the DMD parameters.

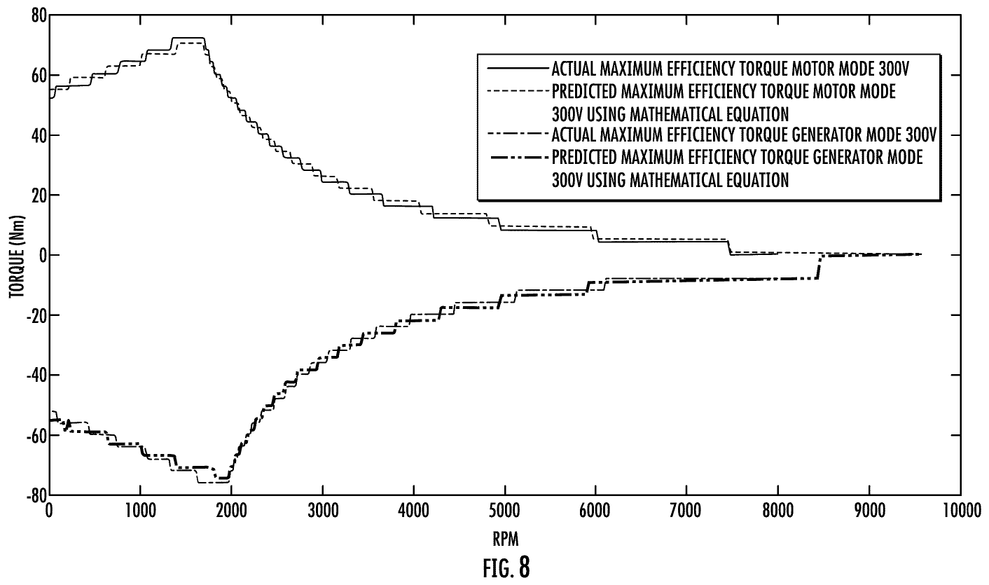

With reference to FIGS. 8-10, the accuracy of mathematical equations to predict various DMD parameters in real-time are illustrated in accordance with embodiments of the present disclosure. Referring initially to FIG. 8, the comparison of actual maximum efficient torque versus the predicted maximum efficient torque is shown for a 300V DC Input Voltage for a SynRM. From the chart, the predictions of the mathematical equation closely match the trend and the actual values substantiating that the method 700 can be used to efficiently predict the maximum efficient torque in real-time.

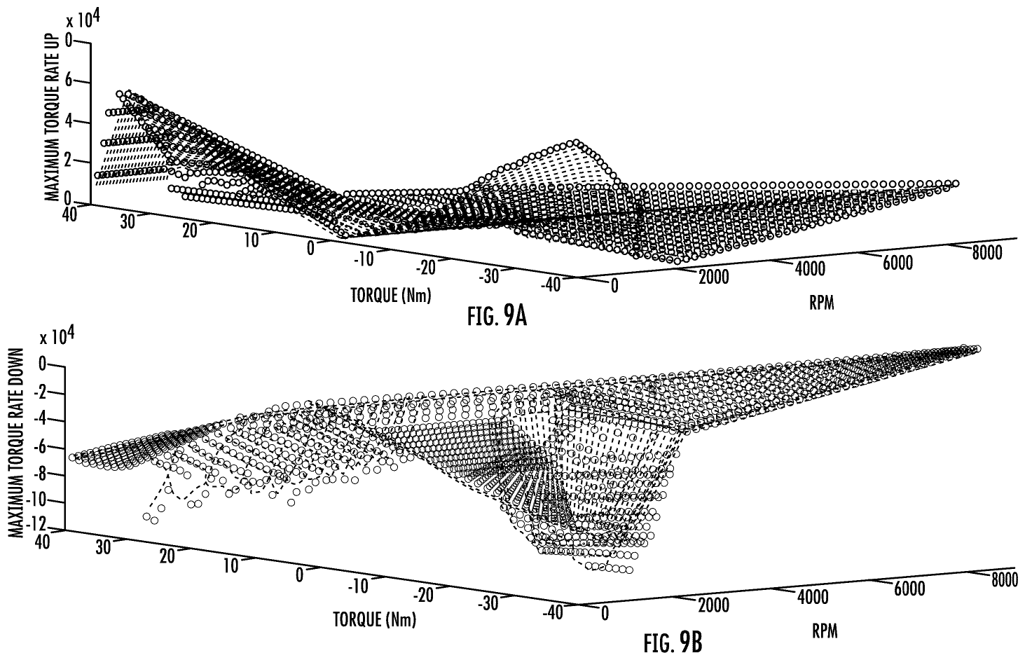

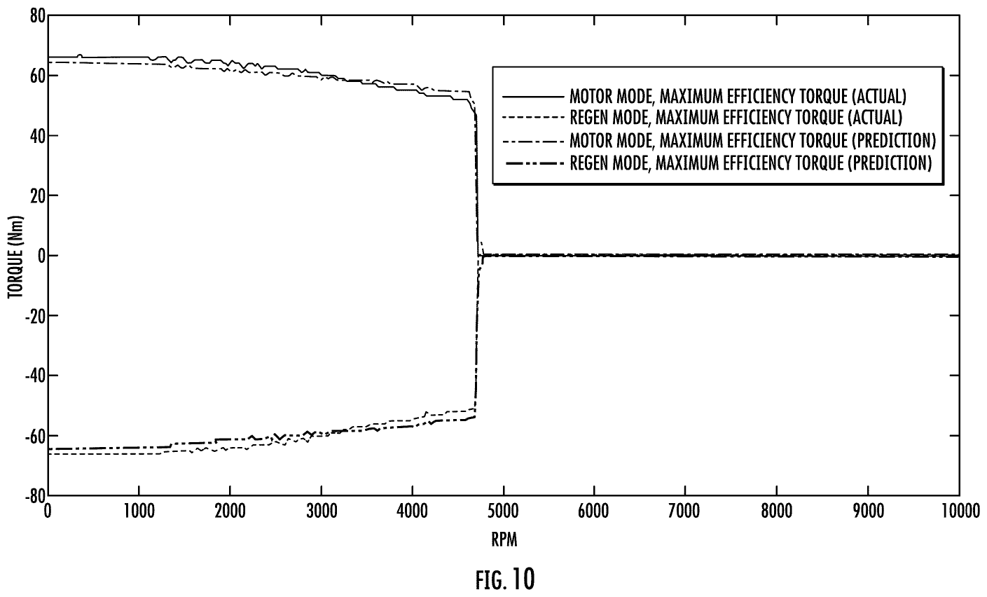

As shown in FIGS. 9A and 9B, the comparison of actual maximum torque ramp up/down rate versus the predicted maximum torque ramp up/down rate for a SynRM is shown using a mathematical equation and DC input voltage as an input variable. From the chart, the predictions of the mathematical equation closely match the trend and the actual values substantiating that the method 700 (FIG. 7D) can be used to efficiently predict the maximum torque ramp up/down rate.

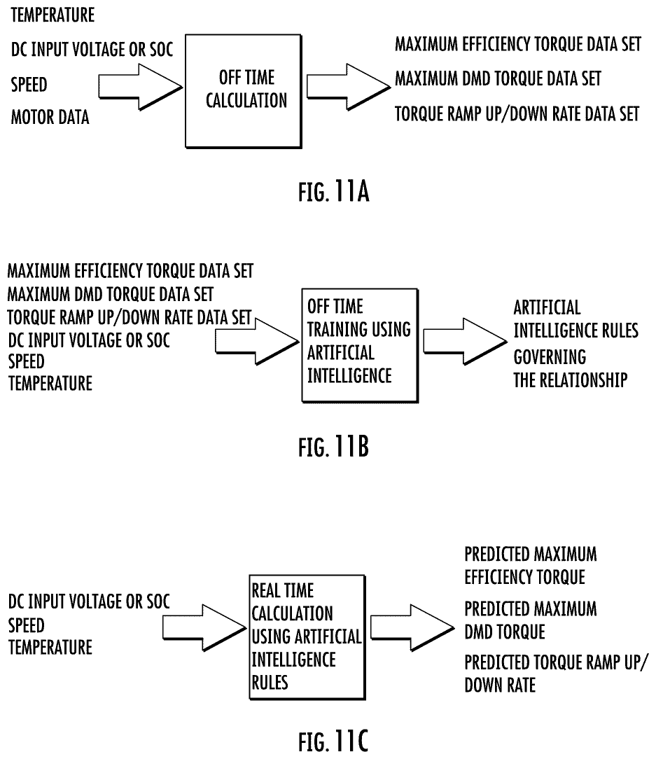

As shown in FIG. 10, the comparison of actual maximum efficient torque versus the predicted maximum efficient torque for an IPM machine is shown using a mathematical equation and DC input voltage of the electric machine or a state of charge of the battery system as an input variable. From the chart, the predictions of the mathematical equation closely match the trend and the actual values substantiating that the method 700 can be used to efficiently predict the maximum efficient torque.

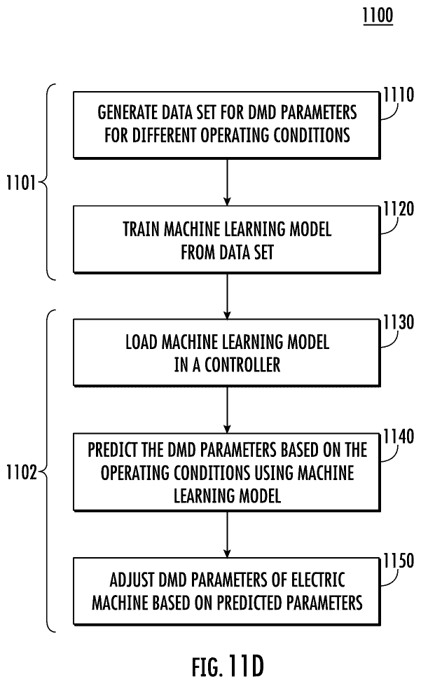

FIGS. 11A-11D illustrate a procedure for developing and using a machine learning (ML) model to predict DMD parameters in real-time for a variety of operating conditions in accordance with an embodiment of the present disclosure. In particular, FIG. 11D illustrates a method 1100 for developing and using a machine learning model for predicting DMD parameters in real-time. The method 1100 includes a method 1101 of defining relationships between DMD parameters and operating conditions and method 1102 of predicting DMD parameters in real-time based on operating conditions of the electric machine. The method 1101 includes generating a data set for the actual DMD parameters for a variety of operating conditions of the electric motor (Step 1110). The DMD parameters may include the optimal efficient torque or optimal pulse torque, the maximum DMD torque line, and/or the maximum torque ramp up/down rate for the electric motor for the operating conditions. The operating conditions may include DC input voltage or SOC of the battery, speed of the electric machine, and/or the temperature of the electric machine or the inverter.

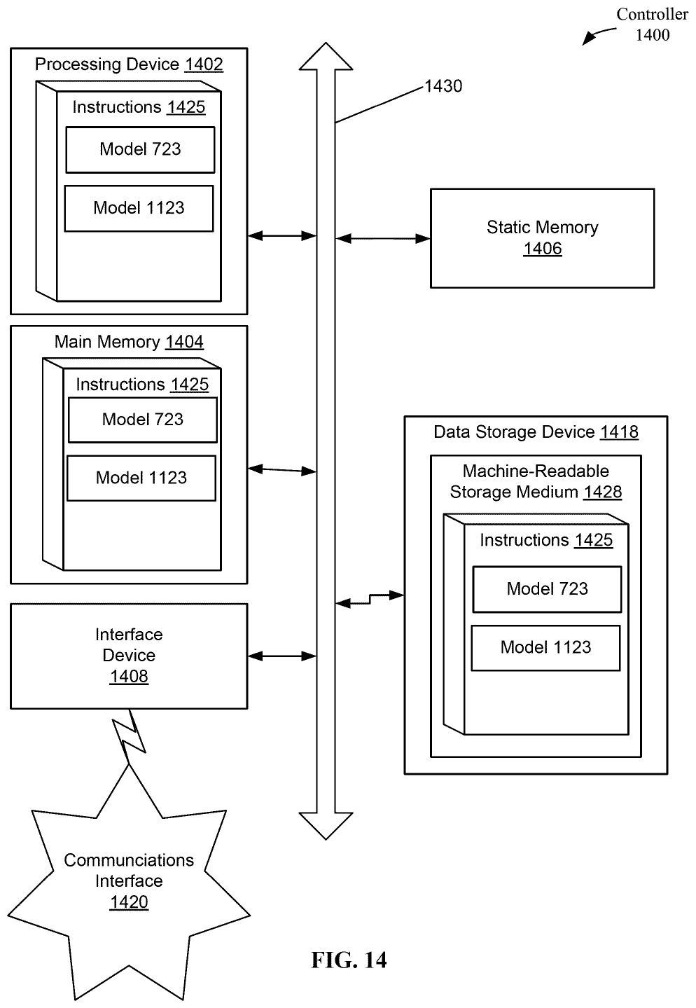

From the data set, a machine learning model 1123 (FIG. 14) is trained to define the relationship between the DMD parameters and the operating conditions (Step 1120). The machine learning model 1123 may be trained using regression machine learning methods including, but not limited to, linear regression, tree-based models (random forest, gradient boosting tree), support vector machine, and artificial neural networks.

Once the relationship between the DMD parameters and the operating conditions are defined via method 1101, the method 1102 is implemented to predict the DMD parameters in real-time with the machine learning model trained by the method 1101. To predict the DMD parameters, rules of the machine learning model are loaded into the memory of a controller, e.g., controller 38 (FIG. 3) (Step 1130). With the rules of the machine learning model loaded into the controller, the operating conditions are provided to the controller which applies the machine learning rules to predict the DMD parameters for the operating conditions provided (Step 1140).

The controller may adjust the DMD parameters of the electric machine in view of the predicted parameters (Step 1150). Adjusting the DMD parameters of the electric machine may increase the efficiency of the electric machine. In some embodiments, adjusting the DMD parameters may result in the electric machine transitioning to continuous control mode instead of pulsed control mode.

Using a machine learning model to predict the DMD parameters based on the operating conditions may allow for real-time prediction of the DMD parameters. The machine learning model may alleviate resources usage, e.g., storage and processing power, to predict the DMD parameters.

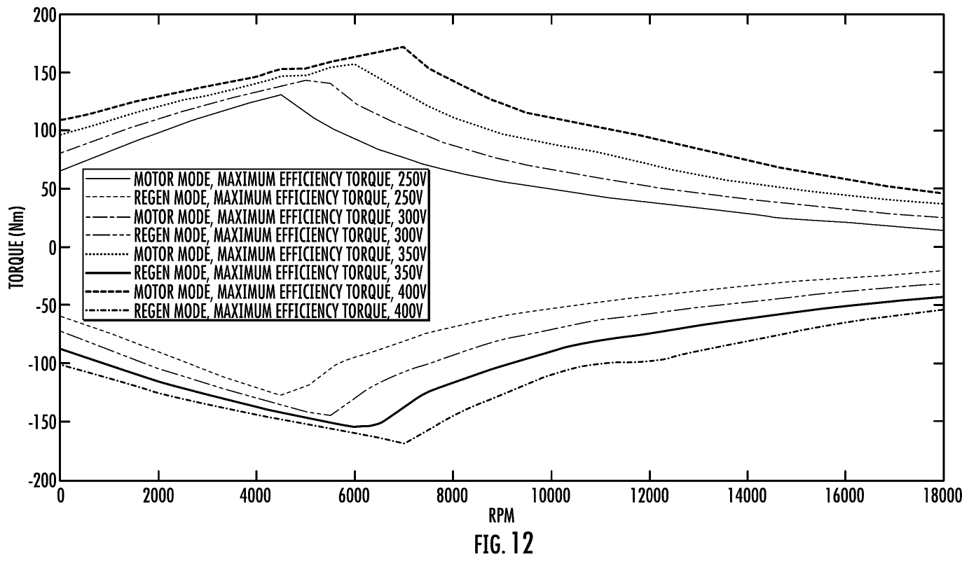

FIG. 12 illustrates a comparison of a maximum efficiency torque versus RPM of an example EESM for various DC voltages. From the chart, the maximum efficient torque increases in motor mode, or decreases in regen mode, to a peak efficient torque as the RPM of the EESM increases and then the maximum efficient torque decreases as the RPM of the EESM increases. As shown, the peak efficient torque and the RPM at which the peak efficient torque increases as the voltage of the EESM increases.

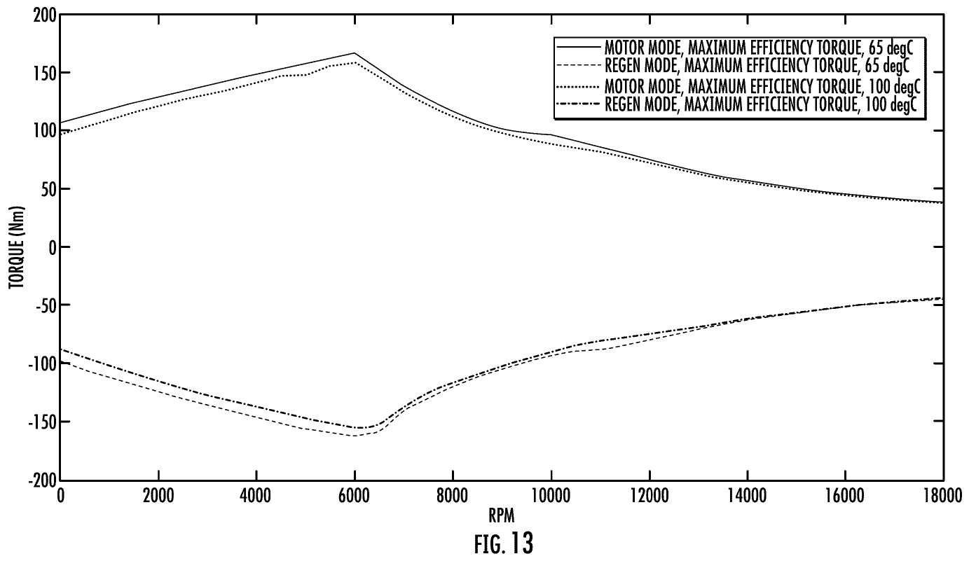

FIG. 13 illustrates a maximum efficiency torque with respect to RPM of an example EESM for various winding temperatures. From the chart, the maximum efficient torque increases in motor mode, or decreases in regen mode, to a peak efficient torque as the RPM of the EESM increases and then the maximum efficient torque decreases as the RPM of the EESM increases. As shown, the peak efficient torque decreases as the temperature of the windings of the EESM increases but the RPM at which the peak efficient torque occurs remains substantially the same.

The maximum efficiency torque versus RPM for given conditions may be used to train a machine learning model in a controller, e.g., controller 36. For example, an example EESM may be operated in various conditions over a range of RPMs for the EESM to generate data to train a machine learning model. The machine learning model may then be used to predict a maximum efficient torque for real-time operating conditions of the EESM or possibly another EESM.

FIG. 14 is a block diagram of an example controller 1400 that may perform one or more of the operations described herein, in accordance with some embodiments. For example, the controller 1400 may be used as the controller 38 detailed above. The controller 1400 may be in signal communication with other computing devices or controllers by being integrated therewithin or connected via a LAN, an intranet, an extranet, and/or the Internet. In some embodiments, while only a single controller is illustrated, the term “controller” may be taken to include any collection of controllers that individually or jointly execute a set (or multiple sets) of instructions to perform the methods discussed herein.

The example controller 1400 may include a processing device (e.g., a general-purpose processor, a PLD, etc.) 1402, a main memory 1404 (e.g., synchronous dynamic random access memory (DRAM), read-only memory (ROM)), a static memory 1406 (e.g., flash memory and a data storage device 1418), which may communicate with each other via a bus 1430.

Processing device 1402 may be provided by one or more general-purpose processing devices such as a microprocessor, central processing unit, or the like. In an illustrative example, processing device 1402 may comprise a complex instruction set computing (CISC) microprocessor, reduced instruction set computing (RISC) microprocessor, very long instruction word (VLIW) microprocessor, or a processor implementing other instruction sets or processors implementing a combination of instruction sets. Processing device 1402 may comprise one or more special-purpose processing devices such as an application specific integrated circuit (ASIC), a field programmable gate array (FPGA), a digital signal processor (DSP), network processor, or the like. The processing device 1402 may be configured to execute the operations described herein, in accordance with one or more aspects of the present disclosure, for performing the operations and steps discussed herein.

The data storage device 1418 may include a computer-readable storage medium 1428 on which may be stored one or more sets of instructions 1425 that may include instructions for one or more components (e.g., the models 723, 1123) for carrying out the operations described herein, in accordance with one or more aspects of the present disclosure. Instructions 1425 may reside, completely or at least partially, within main memory 1404 and/or within processing device 1402 during execution thereof by computing device 1400, main memory 1404 and processing device 1402 constituting computer-readable media. The instructions 1425 may be transmitted or received over a communication interface 1420 via interface device 1408.

While computer-readable storage medium 1428 is shown in an illustrative example to be a single medium, the term “computer-readable storage medium” should be taken to include a single medium or multiple media (e.g., a centralized or distributed database and/or associated caches and servers) that store the one or more sets of instructions. The term “computer-readable storage medium” may be taken to include any medium that is capable of storing, encoding, or carrying a set of instructions for execution by the machine and that causes the machine to perform the methods described herein. The term “computer-readable storage medium” shall accordingly be taken to include, but not be limited to, solid-state memories, optical media, and magnetic media.

Examples described herein may relate to an apparatus for performing the operations described herein. This apparatus may be specially constructed for the required purposes, or it may comprise a general-purpose computing device selectively programmed by a computer program stored in the computing device. Such a computer program may be stored in a computer-readable non-transitory storage medium.

The methods and illustrative examples described herein are not inherently related to any particular computer or other apparatus. Various general-purpose systems may be used in accordance with the teachings described herein, or it may prove convenient to construct more specialized apparatus to perform the required method steps. The required structure for a variety of these systems will appear as set forth in the description above.

The terms “comprises”, “comprising”, “includes”, and/or “including”, when used herein, may specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

In some embodiments, the functions/acts noted may occur out of the order noted in the figures. For example, two figures shown in succession may in fact be executed substantially concurrently or may sometimes be executed in the reverse order, depending upon the functionality/acts involved.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

Various units, circuits, or other components may be described or claimed as “configured to” or “configurable to” perform a task or tasks. In such contexts, the phrase “configured to” or “configurable to” is used to connote structure by indicating that the units/circuits/components include structure (e.g., circuitry) that performs the task or tasks during operation. As such, the unit/circuit/component can be said to be configured to perform the task, or configurable to perform the task, even when the specified unit/circuit/component is not currently operational (e.g., is not on). The units/circuits/components used with the “configured to” or “configurable to” language include hardware—for example, circuits, memory storing program instructions executable to implement the operation, etc. Reciting that a unit/circuit/component is “configured to” perform one or more tasks, or is “configurable to” perform one or more tasks, is expressly intended not to invoke 35 U.S.C. 112, sixth paragraph, for that unit/circuit/component. Additionally, “configured to” or “configurable to” can include generic structure (e.g., generic circuitry) that is manipulated by software and/or firmware (e.g., an FPGA or a general-purpose processor executing software) to operate in a manner that is capable of performing the task(s) at issue. “Configured to” may include adapting a manufacturing process (e.g., a semiconductor fabrication facility) to fabricate devices (e.g., integrated circuits) that are adapted to implement or perform one or more tasks. “Configurable to” is expressly intended not to apply to blank media, an unprogrammed processor or an unprogrammed generic computer, or an unprogrammed programmable logic device, programmable gate array, or other unprogrammed device, unless accompanied by programmed media that confers the ability to the unprogrammed device to be configured to perform the disclosed function(s).

The foregoing description, for the purpose of explanation, has been described with reference to specific embodiments. However, the illustrative discussions above are not intended to be exhaustive or to limit the present embodiments to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the present embodiments are not to be limited to the details given herein, but may be modified within the scope and equivalents of the appended claims.

While several embodiments of the disclosure have been shown in the drawings, it is not intended that the disclosure be limited thereto, as it is intended that the disclosure be as broad in scope as the art will allow and that the specification be read likewise. Any combination of the above embodiments is also envisioned and is within the scope of the appended claims. Therefore, the above description should not be construed as limiting, but merely as exemplifications of particular embodiments. Those skilled in the art will envision other modifications within the scope of the claims appended hereto.

What is claimed:

1. A method of predicting torque modulation parameters of an electric machine based on operating conditions of the electric machine, the method comprising:
generating a data set for torque modulation parameters of an electric machine for different operating conditions of the electric machine;
relating the torque modulation parameters to the operating conditions of the electric machine with a model;
loading the model into a controller of the electric machine; and
predicting the torque modulation parameters of the electric machine for the operating conditions of the electric machine using the model in real-time.

2. The method of claim 1, further comprising adjusting the torque modulation parameters of the electric machine based on the predicted torque modulation parameters.

3. The method of claim 1, wherein relating the torque modulation parameters to the operating conditions of the electric machine with the model includes developing a mathematical equation for the relationship between the torque modulation parameters and the operating conditions using the data sets.

4. The method of claim 3, wherein loading the model into the controller include generating a baseline data set for the torque modulation parameters for different operating conditions.

5. The method of claim 4, wherein predicting the torque modulation parameters for the operating conditions includes utilizing the baseline data set and the mathematical equation to predict the torque modulation parameters.

6. The method of claim 1, wherein relating the torque modulation parameters to the operating conditions of the electric machine with the model includes training a machine learning model for the relationship between the torque modulation parameters and the operating conditions using the data sets.

7. The method of claim 6, wherein loading the model into the controller include loading the machine learning model into the controller.

8. The method of claim 7, wherein predicting the torque modulation parameters for the operating conditions includes utilizing the machine learning model in the controller to predict the torque modulation parameters.

9. The method of claim 1, wherein generating a data set for torque modulation parameters of an electric machine for different operating conditions of the electric machine includes the torque modulation parameters including maximum efficient pulse torque, maximum DMD torque for pulse control, or maximum torque ramp up/down.

10. The method of claim 1, wherein generating a data set for torque modulation parameters of an electric machine for different operating conditions of the electric machine includes the operating conditions including DC input voltage, state of charge of a battery, speed of the electric machine, temperature of the electric machine, or temperature of an inverter of the electric machine.

11. A controller for controlling an electric machine, the controller comprising:
a memory; and
a processing device, operatively coupled to the memory, to:
store a model relating operating conditions of the electric machine to torque modulation parameters of the electric machine; and
predict the torque modulation parameters of the electric machine for the operating conditions of the electric machine using the model in real-time.

12. The controller of claim 11, wherein the processing device further adjusts the torque modulation parameters of the electric machine based on the predicted torque modulation parameters.

13. The controller of claim 11, wherein storing the model relating operating conditions to the electric machine includes storing a mathematical equation for the relationship between the torque modulation parameters and the operating conditions.

14. The controller of claim 11, wherein storing the model relating the operating conditions to the electric machine includes storing a machine learning model for the relationship between the torque modulation parameters and the operating conditions.

15. The controller of claim 14, wherein predicting the torque modulation parameters for the operating conditions includes utilizing the machine learning model to predict the torque modulation parameters.

16. A non-transitory computer-readable medium storing instructions that, when executed by a processing device, cause the processing device to control an electric machine by:
storing a model relating operating conditions of the electric machine to torque modulation parameters of the electric machine; and
predicting the torque modulation parameters of the electric machine for the operating conditions of the electric machine using the model in real-time.

17. The non-transitory computer-readable medium of claim 16, wherein the processing device is further caused to adjust the torque modulation parameters of the electric machine based on the predicted torque modulation parameters.

18. The non-transitory computer-readable medium of claim 16, wherein storing the model relating operating conditions to the electric machine includes storing a mathematical equation for the relationship between the torque modulation parameters and the operating conditions.

19. The non-transitory computer-readable medium of claim 16, wherein storing the model relating the operating conditions to the electric machine includes storing a machine learning model.

20. The non-transitory computer-readable medium of claim 19, wherein predicting the torque modulation parameters for the operating conditions includes utilizing the machine learning model to predict the torque modulation parameters.
